(19) United States
(12) Patent Application Publication
(10) Pub. No.: US 2019/0067645 A1
(43) Pub. Date: Feb. 28, 2019

(54) DISPLAY DEVICE

(71) Applicant: Samsung Display Co., Ltd., Yongin-si (KR)

(72) Inventors: Hyeonbum Lee, Yongin-si (KR); Jinwhan Jung, Yongin-si (KR); Kwangwoo Park, Yongin-si (KR); Dongki Lee, Yongin-si (KR)

(21) Appl. No.: 15/860,514

(22) Filed: Jan. 2, 2018

(30) Foreign Application Priority Data
Aug. 25, 2017 (KR) 10-2017-0108137

(51) Int. Cl. H01L 51/52; H01L 51/00; G02F 1/1333; G02F 1/1335

(52) U.S. Cl. CPC H01L 51/5275; H01L 51/0097; G02F 2201/56; G02F 1/133526; G02F 2001/133562; G02F 1/133305

(57) ABSTRACT

A display device includes: a substrate including a first area, a second area, and a first bent area between the first area and the second area, the substrate being bent around a first bending axis in the first bent area; a display surface over the substrate in the first area and the first bent area; and a first light adjustment layer over the display surface and overlapping the first bent area, the first light adjustment layer including a first upper surface, the first supper surface including a first portion and a second portion, the first portion being located closer to the first area than the second portion, the first upper surface being oblique with respect to the display surface such that a shortest distance to the display surface from the first portion is longer than a shortest distance to the display surface from the second portion.

### CROSS-REFERENCE TO RELATED APPLICATION

This application claims priority to and the benefit of Korean Patent Application No. 10-2017-0108137, filed on Aug. 25, 2017 in the Korean Intellectual Property Office, the entire disclosure of which is incorporated herein by reference.

### BACKGROUND

### 1. Field

Aspects of one or more embodiments relate to a display device.

### 2. Description of the Related Art

Generally, a display device displays an image to allow a user to recognize the image. Therefore, the display device needs to accurately display an image. However, in a display device in which a display surface thereof is partially bent, even when an entire display area displays the same image, color at a bent portion recognized by a user may be different from color at a non-bent portion recognized by the user. That is, when a user views a bent area in a direction perpendicular to a display surface inside the bent area, an image of intended color is recognized even inside the bent area, but when the user views the bent area in a direction perpendicular to a display surface at a flat portion which is not the bent area, color of the image displayed inside the bent area is recognized as color closer to blue than the intended color.

### SUMMARY

According to an aspect of one or more embodiments, a display device may improve the quality of an image displayed in various portions of the display device. However, this aspect is provided as an example, and the scope of the present disclosure is not limited thereto.

Additional aspects will be set forth, in part, in the description which follows and, in part, will be apparent from the description, or may be learned by practice of the presented embodiments.

According to one or more embodiments, a display device includes: a substrate including a first area, a second area, and a first bent area arranged between the first area and the second area, the substrate being bent around a first bending axis in the first bent area; a display surface over the substrate in the first area and the first bent area; and a first light adjustment layer over the display surface and overlapping the first bent area, the first light adjustment layer including a first upper surface, the first upper surface including a first portion and a second portion, the first portion being located closer to the first area than the second portion, the first upper surface being oblique with respect to the display surface such that a shortest distance to the display surface from the first portion is longer than a shortest distance to the display surface from the second portion.

The first light adjustment layer may further include a second upper surface over the display surface and overlapping the first bent area such that the second upper surface is arranged farther away from the first area than the first upper surface, the second upper surface including a third portion and a fourth portion, the third portion being located closer to the first area than the fourth portion, the second upper surface being oblique with respect to the display surface such that a shortest distance to the display surface from the third portion is longer than a shortest distance to the display surface from the fourth portion.

A second virtual plane connecting the third portion and the fourth portion may be more oblique with respect to the display surface in the first area than a first virtual plane connecting the first portion and the second portion.

The first upper surface and the second upper surface may be spaced apart from each other, or connected to each other.

The substrate may include a third area at a side of the first area in a direction away from the second area, and a second bent area between the first area and the third area, the substrate being bent around a second bending axis in the second bent area, the display surface may extend to the second bent area, and the display device may further include a second light adjustment layer over the display surface and overlapping the second bent area, the second light adjustment layer including a third upper surface, the third upper surface including a fifth portion and a sixth portion, the fifth portion being located closer to the first area than the sixth portion, the third upper surface being oblique with respect to the display surface such that a shortest distance to the display surface from the fifth portion is longer than a shortest distance to the display surface from the sixth portion.

The second bending axis may be parallel to the first bending axis.

The second light adjustment layer may further include a fourth upper surface over the display surface and overlapping the second bent area such that the fourth upper surface is arranged farther away from the first area than the third upper surface, the fourth upper surface including a seventh portion and an eighth portion, the seventh portion being located closer to the first area than the eighth portion, the fourth upper surface being oblique with respect to the display surface such that a shortest distance to the display surface from the seventh portion is longer than a shortest distance to the display surface from the eighth portion.

A fourth virtual plane connecting the seventh portion and the eighth portion may be more oblique with respect to the display surface in the first area than a third virtual plane connecting the fifth portion and the sixth portion.

The third upper surface and the fourth upper surface may be spaced apart from each other, or connected to each other.

According to one or more embodiments, a display device includes: a substrate including a first area, a second area, and a first bent area arranged between the first area and the second area, the substrate being bent around a first bending axis in the first bent area; a display surface over the substrate in the first area, the first bent area, and the second area; and a first light adjustment layer over the display surface and overlapping the second area, the first light adjustment layer including a first upper surface, the first upper surface including a first portion and a second portion, the first portion being located closer to the first area than the second portion, the first upper surface being oblique with respect to the display surface such that a shortest distance to the display surface from the first portion is longer than a shortest distance to the display surface from the second portion.

The first light adjustment layer may further include a second upper surface over the display surface and overlapping the second area such that the second upper surface is arranged farther away from the first area than the first upper surface, the second upper surface including a third portion and a fourth portion, the third portion being located closer to the first area than the fourth portion, the second upper surface being oblique with respect to the display surface such that a shortest distance to the display surface from the third portion is longer than a shortest distance to the display surface from the fourth portion.

A first virtual plane connecting the first portion and the second portion may be parallel to a second virtual plane connecting the third portion and the fourth portion.

The first upper surface and the second upper surface may be spaced apart from each other, or connected to each other.

According to an aspect of one or more embodiments, a display device which may improve the quality of an image displayed in various portions of the display device may be implemented. However, the scope of the present disclosure is not limited by this effect.

### BRIEF DESCRIPTION OF THE DRAWINGS

These and/or other aspects will become apparent and more readily appreciated from the following description of some embodiments, taken in conjunction with the accompanying drawings in which:

FIG. 1 is a perspective view of a portion of a display device according to an embodiment;

FIG. 2 is a side view of a portion of the display device of FIG. 1;

FIG. 3 is a conceptual side view of a traveling direction of light in a display device according to a comparative example;

FIG. 4 is a side view of a portion of a display device according to another embodiment;

FIG. 5 is a side view of a portion of a display device according to another embodiment;

FIG. 6 is a side view of a portion of a display device according to another embodiment;

FIG. 7 is a side view of a portion of a display device according to another embodiment;

FIG. 8 is a side view of a portion of the display device of FIG. 7;

FIG. 9 is a side view of a portion of a display device according to another embodiment;

FIG. 10 is a side view of a portion of a display device according to another embodiment;

FIG. 11 is a side view of a portion of a display device according to another embodiment;

FIG. 12 is a side view of a portion of a display device according to another embodiment;

FIG. 13 is a side view of a portion of a display device according to another embodiment;

FIG. 14 is a side view of a portion of a display device according to another embodiment; and

FIG. 15 is a side view of a portion of a display device according to another embodiment.

### DETAILED DESCRIPTION

As the present disclosure allows for various changes and numerous embodiments, some example embodiments will be illustrated in the drawings and described in further detail in the following description. Effects and characteristic of the disclosure, and methods of accomplishing these will be apparent when referring to embodiments described with reference to the drawings. This disclosure may, however, be embodied in many different forms and should not be construed as limited to the example embodiments set forth herein.

Herein, the disclosure will be described more fully with reference to the accompanying drawings, in which some example embodiments of the disclosure are shown. When description is made with reference to the drawings, like reference numerals in the drawings denote like or corresponding elements, and repeated description thereof will be omitted.

It will be understood that when a component, such as a layer, a film, a region, or a plate, is referred to as being “on” another component, the component can be directly on the other component or one or more intervening components may be present thereon. Sizes of elements in the drawings may be exaggerated for convenience of explanation. In other words, since sizes and thicknesses of components in the drawings may be arbitrarily illustrated for convenience of explanation, the following embodiments are not limited thereto.

In the following examples, the x-axis, the y-axis, and the z-axis are not limited to three axes of a rectangular coordinate system, and may be interpreted in a broader sense. For example, the x-axis, the y-axis, and the z-axis may be perpendicular to one another, or may represent different directions that are not perpendicular to one another.

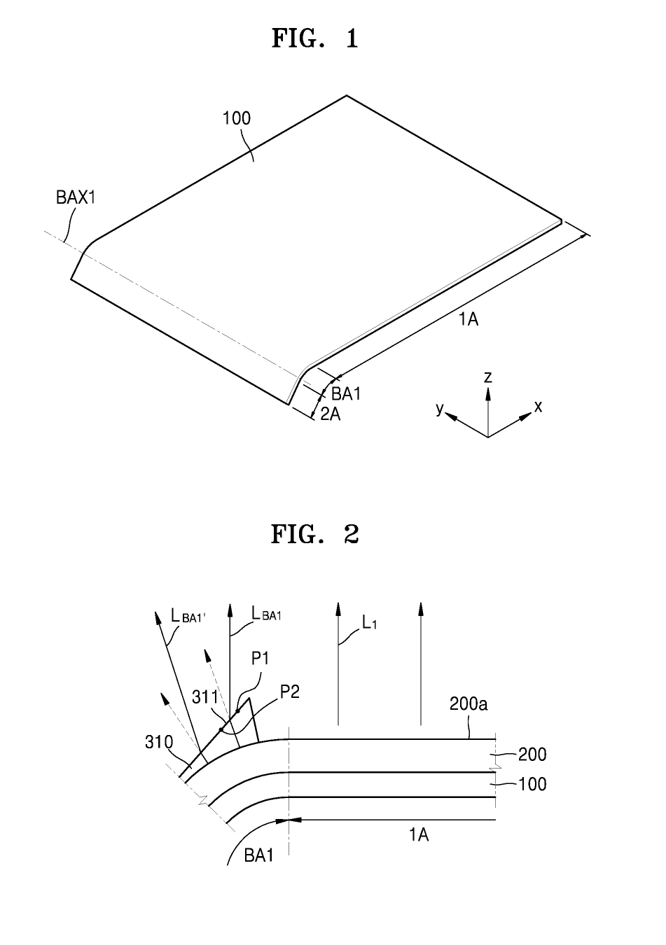

FIG. 1 is a perspective view of a portion of a display device according to an embodiment; and FIG. 2 is a side view of a portion of the display device of FIG. 1. The display device according to the present embodiment includes a substrate 100, a display surface 200a, and a first light adjustment layer 310.

As illustrated in FIG. 1, the substrate 100 includes a first area 1A, a second area 2A, and a first bent area BA1. The first bent area BA1 is arranged between the first area 1A and the second area 2A, and the substrate 100 is bent around a first bending axis BAX1 extending in a direction (e.g., a y-axis direction) in the first bent area BA1. Accordingly, the display surface 200a of the display device also includes a bent portion over the first bent area BA1. The display surface 200a may have a substantially flat shape in at least one of the first area 1A or the second area 2A.

The substrate 100 may include any of various flexible or bendable materials, e.g., any of polymer resins such as polyethersulfone (PES), polyacrylate (PAR), polyetherimide (PEI), polyethylene naphthalate (PEN), polyethylene terephthalate (PET), polyphenylene sulfide (PPS), polyarylate (PAR), polyimide (PI), polycarbonate (PC), or cellulose acetate propionate (CAP). The substrate 100 may have a multi-layered structure including two layers including the above polymer resins, and a barrier layer including an inorganic material (such as a silicon oxide, a silicon nitride, or a silicon oxynitride) arranged between the two layers, and may be modified variously.

Although FIG. 1 illustrates that the substrate 100 is slightly bent in the first bent area BA1, embodiments are not limited thereto. For example, the substrate 100 may be bent in the first bent area BA1 such that at least a portion of the first area 1A and at least a portion of the second area 2A may face each other. That is, at least a portion of the second area 2A may be arranged below a back side of the first area 1A in a (−) z-axis direction with reference to the coordinate axes illustrated in FIG. 1. The same is true of embodiments and modified examples described below.

As illustrated in FIG. 2, a display unit 200 is arranged over the substrate 100. The display unit 200 is arranged in not only the first area 1A but also in at least a portion of the first bent area BA1. Accordingly, the display surface 200a, which is an upper surface (in a generally (+) z-axis direction) of the display unit 200, is arranged over the substrate 100 in the first area 1A and the first bent area BA1.

The display unit 200 may include any of various display elements. For example, the display unit 200 may include an organic light-emitting diode (OLED) including a pixel electrode, an intermediate layer over the pixel electrode and including an emission layer, and an opposite electrode over the intermediate layer. Alternatively, the display unit 200 may include a liquid crystal element, for example. An encapsulation layer having a multi-layered structure including an organic layer/an inorganic layer/an organic layer, etc., or a color filter layer in which a black matrix and a color filter are alternately arranged over a same plane, or a polarization layer, etc. may be arranged over a display element as desired. A unit including such structures may be referred to as the display unit 200 for convenience of description, and the display unit 200 may be modified variously. The same is true of embodiments and modified examples described below.

The first light adjustment layer 310 is arranged over the display surface 200a in or overlapping the first bent area BA1. The first light adjustment layer 310 adjusts a traveling direction of light emitted from the display surface 200a in the first bent area BA1. For this, the first light adjustment layer 310 includes a first upper surface 311. As illustrated in the side view, the first upper surface 311 includes a first portion P1 and a second portion P2, among which the first portion P1 is located closer to the first area 1A, and a shortest distance to the display surface 200a from the first portion P1 is longer than a shortest distance to the display surface 200a from the second portion P2. In an embodiment, the first upper surface 311 having a flat form is oblique with respect to the display surface 200a over the first bent area BA1.

The first light adjustment layer 310 may include, for example, a silicon nitride or a silicon oxide, or may include any of various polymer resins. A refractive index of the first light adjustment layer 310 is higher than that of air. A layer covering the first light adjustment layer 310 may be provided. In this case, a refractive index of the first light adjustment layer 310 may be higher than that of the layer covering the first light adjustment layer 310. The same is true of embodiments and modified examples described below.

Light emitted from one point on the display surface 200a progresses in various directions. However, most of light emitted from one point on the display surface 200a travels in a direction approximately perpendicular to the display surface 200a at the relevant point, and some of the light travels in other directions. Therefore, herein, light emitted from one point on the display surface 200a is described as travelling in a direction perpendicular to the display surface 200a at the relevant point, for convenience of description. The same is true of embodiments and modified examples described below.

As illustrated in FIG. 2, light L₁ emitted from the display surface 200a in the first area 1A progresses in a direction perpendicular to the display surface 200a. Since the display surface 200a has a flat form in the first area 1A, portions of light emitted from the display surface 200a in the first area 1A travel in parallel with each other. Light L_{BA1} and light L_{BA1′} emitted from the display surface 200a in the first bent area BA1 also travel in a direction perpendicular to the display surface 200a. However, since the display surface 200a in the first bent area BA1 has a bent shape, the light L_{BA1} and the light L_{BA1′} travel in directions which are not parallel to each other on the display surface 200a. The travelling directions of the light L_{BA1} and the light L_{BA1′} on the display surface 200a are not parallel to the travelling direction of the light L₁ from the display surface 200a in the first area 1A.

However, since the first light adjustment layer 310 is provided, the light L_{BA1} and the light L_{BA1′} change their travelling directions while passing through the first light adjustment layer 310. Since the light L_{BA1} is incident at an angle which is not a right angle when passing through the first upper surface 311 of the first light adjustment layer 310, the light L_{BA1} is refracted according to Snell's law while the light L_{BA1} passes through the first upper surface 311. As described above, the refractive index of the first light adjustment layer 310 is higher than that of the outside, such as air, and a shortest distance to the display surface 200a from a portion of the first upper surface 311 adjacent to the first area 1A is longer than a shortest distance to the display surface 200a from a portion of the first upper surface 311 away from the first area 1A. Therefore, the light L_{BA1} changes its travelling direction to a direction toward the first area 1A while passing through the first upper surface 311 of the first light adjustment layer 310. Accordingly, as illustrated in FIG. 2, the travelling direction of the light L_{BA1} may be parallel or approximately parallel to the travelling direction of the light L₁ in the first area 1A.

The travelling direction of the light L_{BA1′} emitted from a point on the display surface 200a farther away from the first area 1A than the point on the display surface 200a from which the light L_{BA1} is emitted is also changed to a direction toward the first area 1A while passing through the first upper surface 311 of the first light adjustment layer 310. Although an angle between the travelling direction of the light L_{BA1′} after passing through the first light adjustment layer 310 and the travelling direction of the light L₁ in the first area 1A is greater than an angle between the light L_{BA1} after passing through the first light adjustment layer 310 and the travelling direction of the light L₁ in the first area 1A, the angle between the travelling direction of the light L_{BA1′} after passing through the first light adjustment layer 310 and the travelling direction of the light L₁ in the first area 1A may be made remarkably smaller than an angle between the travelling direction of the light L_{BA1} emitted from the display surface 200a inside the first bent area BA1 and the travelling direction of the light L₁.

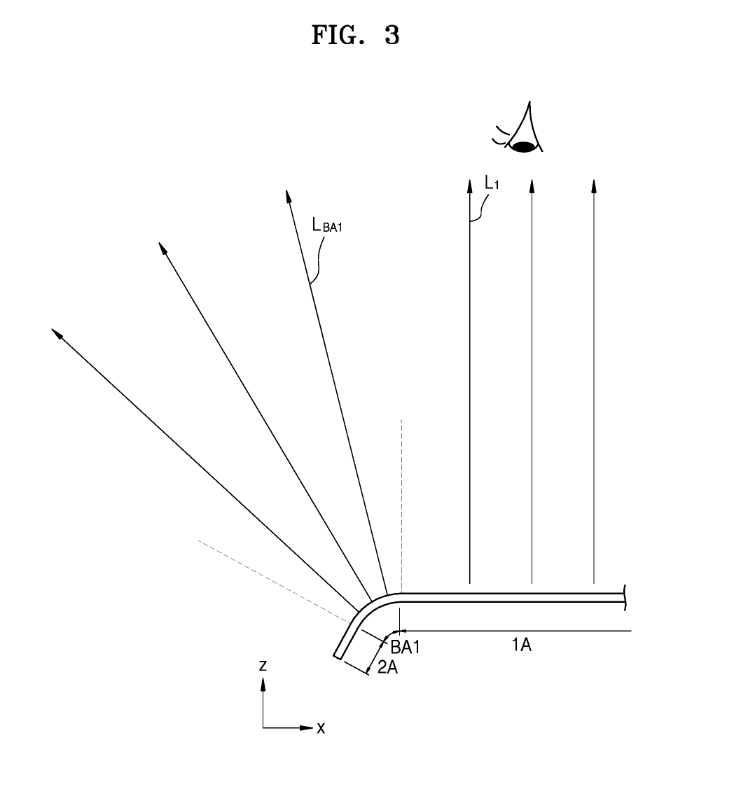

FIG. 3 is a conceptual side view of a travelling direction of light in a display device according to a comparative example. In the comparative example, the first light adjustment layer 310 is absent, as illustrated in FIG. 3, and the travelling direction of the light L_{BA1} in the first bent area BA1 forms a considerably large angle with respect to the travelling direction of the light L₁ in the first area 1A. Since a user of a mobile apparatus, such as a smartphone or a smart watch, mainly views a display unit in a direction approximately perpendicular to the first area 1A, only a portion of light in the first bent area BA1 is recognized by the user, and, consequently, the color of an image in the first bent area BA1 is recognized as color closer to blue than the intended color. When spectral analysis is performed, a peak in red/green/blue light from a direction in which an angle formed by a virtual straight line with respect to a direction perpendicular to the display surface is large moves toward a shorter wavelength relative to a peak in red/green/blue light from the direction perpendicular to the display surface.

However, since the display device according to the present embodiment includes the first light adjustment layer 310 as described above, the travelling directions of the light L_{BA1} and the light L_{BA1′} in the first bent area BA1 may be adjusted such that the travelling directions of the light L_{BA1} and the light L_{BA1′} in the first bent area BA1 are approximately the same or not much different from the travelling direction of the light L₁ in the first area 1A. Accordingly, an image in the first bent area BA1 may be viewed by a user with the color of the image undistorted or with a degree of distortion of the image remarkably reduced. Consequently, the quality of a viewed image may be remarkably improved.

Although FIG. 2 illustrates that an end of the first light adjustment layer 310 in a direction toward the first area 1A has a pointed shape, embodiments are not limited thereto. For example, as illustrated in FIG. 4, which is a side view of a portion of a display device according to another embodiment, an end of the first light adjustment layer 310 in the direction toward the first area 1A may have a curved shape. The same is true of embodiments and modified examples described below.

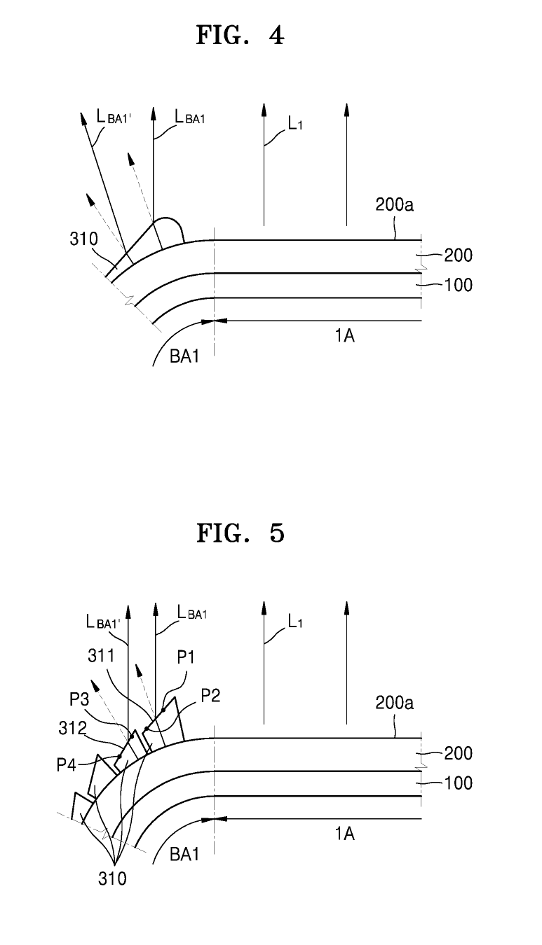

FIG. 5 is a side view of a portion of a display device according to another embodiment. In the display device according to the present embodiment, the first light adjustment layer 310 includes not only the above-described first upper surface 311 but also a second upper surface 312 in or overlapping the first bent area BA1, the second upper surface 312 being arranged in a direction farther away from the first area 1A than the first upper surface 311. As illustrated in the side view, a flat form of the second upper surface 312 may be defined by a third portion P3 and a fourth portion P4. The second upper surface 312 includes the third portion P3 and the fourth portion P4 among which the third portion P3 is located closer to the first area 1A, and the second upper surface 312 is oblique with respect to the display surface 200a such that a shortest distance to the display surface 200a from the third portion P3 is longer than a shortest distance to the display surface 200a from the fourth portion P4.

Particularly, a second virtual plane connecting the third portion P3 and the fourth portion P4, that is, the second upper surface 312, is more oblique with respect to the display surface 200a in the first area 1A than a first virtual plane connecting the first portion P1 and the second portion P2, that is, the first upper surface 311. Accordingly, an angle at which the light L_{BA1′} is incident to a surface of the first light adjustment layer 310 may be made greater than in the embodiment illustrated in FIG. 2. Consequently, an angle by which the light L_{BA1′} is refracted when passing through a surface of the first light adjustment layer 310, that is, the second upper surface 312, may be made larger. Therefore, as illustrated in FIG. 5, the quality of an image viewed by a user may be improved even further by allowing the light L_{BA1′} to travel in parallel with or approximately in parallel with the light L_{BA1}.

For reference, assuming that an incident angle of light travelling inside the first light adjustment layer 310 on an upper surface thereof is ƒ₁, and a refractive angle of the light after passing through the first light adjustment layer 310 is θ₂, θ₂ is greater than θ₁ according to Snell's law. This is because a refractive index of the first light adjustment layer 310 is higher than a refractive index of the outside. Also, since sin θ₁/sin θ₂ is a fixed value according to Snell's law, when θ₁, which is an incident angle, increases, θ₂, which is a refractive angle, also increases. Here, both θ₁ and θ₂ are angles between 0° and 90°. Therefore, under a condition in which θ₂ is greater than θ₁, since sin θ₁/sin θ₂ is a fixed value, when θ₁ increases, θ₂ increases much more than θ₁. Therefore, as illustrated in FIG. 5, the light L_{BA1′} passing through the second upper surface 312 may be made to be refracted much more than the light L_{BA1} passing through the first upper surface 311 by allowing the second upper surface 312 to be more oblique with respect to the display surface 200a in the first area 1A than the first upper surface 311.

Although the first upper surface 311 and the second upper surface 312 of the first light adjustment layer 310 may be spaced apart from each other as illustrated in FIG. 5, embodiments are not limited thereto. For example, although the first light adjustment layer 310 may include a plurality of portions spaced apart from each other as illustrated in FIG. 5, the first light adjustment layer 310 may be formed as one body as illustrated in FIG. 6 showing a side view of a portion of a display device according to another embodiment. As shown in FIG. 6, in an embodiment, the first upper surface 311 may be connected to the second upper surface 312.

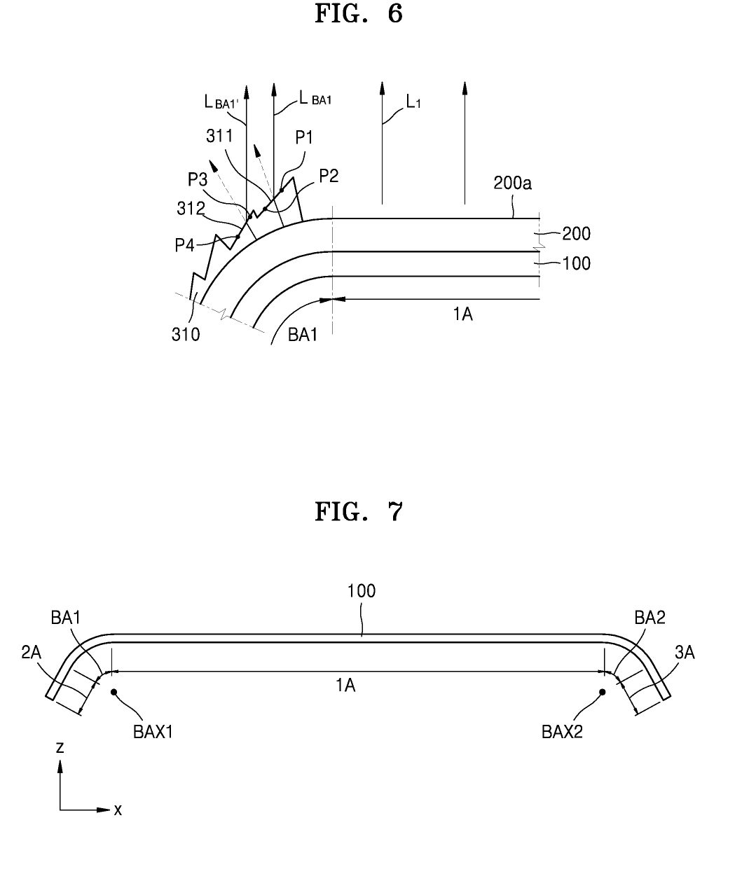

Although embodiments have been described in which the substrate 100 of the display device includes the first area 1A, the first bent area BA1, and the second area 2A, as illustrated in FIG. 1, embodiments are not limited thereto. For example, as illustrated in FIG. 7, which is a side view of a portion of a display device according to another embodiment, and in FIG. 8, which is a side view of a portion of the display device of FIG. 7, the substrate 100 may include a third area 3A at a side of the first area 1A in a direction away from the second area 2A, and a second bent area BA2 arranged between the first area 1A and the third area 3A. The substrate 100 may be bent around a second bending axis BAX2 in the second bent area BA2. In this case, the display unit 200 may extend to the second bent area BA2, and the display surface 200a may also be provided in the second bent area BA2. In an embodiment, for reference, the second bending axis BAX2 may be parallel to the first bending axis BAX1.

In this case, a second light adjustment layer 320 may be provided over the second bent area BA2. That is, the second light adjustment layer 320 may be arranged over the display surface 200a in or overlapping the second bent area BA2. The second light adjustment layer 320 adjusts the travelling direction of light L_{BA2} and light L_{BA2′} emitted from the display surface 200a in the second bent area BA2. For this, the second light adjustment layer 320 includes a third upper surface 321. As illustrated in the side view, the third upper surface 321 includes a fifth portion P5 and a sixth portion P6 among which the fifth portion P5 is closer to the first area 1A, and a shortest distance to the display surface 200a from the fifth portion P5 is longer than a shortest distance to the display surface 200a from the sixth portion P6. In an embodiment, the third upper surface 321 having a flat form is oblique with respect to the display surface 200a over the second bent area BA2.

The second light adjustment layer 320 may include, for example, a silicon nitride or a silicon oxide, or may include any of various polymer resins, etc. The refractive index of the second light adjustment layer 320 is higher than that of air. In an embodiment, a layer covering the second light adjustment layer 320 may be provided. In this case, the refractive index of the second light adjustment layer 320 may be higher than the refractive index of the layer covering the second light adjustment layer 320. The same is true of embodiments and modified examples described below.

Based on the same principle as described with respect to the first light adjustment layer 310, the second light adjustment layer 320 may allow an image in the second bent area BA2 to be viewed by a user with the color of the image undistorted or with a degree of distortion of the image remarkably reduced, thereby improving the quality of the image when viewed.

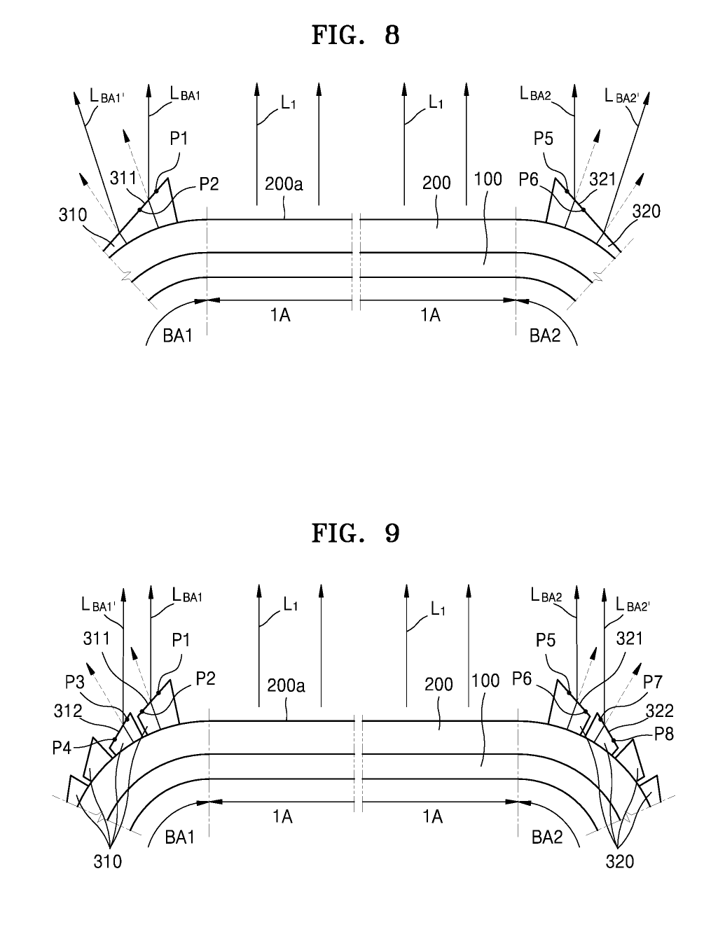

FIG. 9 is a side view of a portion of a display device according to another embodiment. In the display device according to the present embodiment, the first light adjustment layer 310 has the form described with reference to FIG. 5 Also, the second light adjustment layer 320 includes not only the third upper surface 321 described with reference to FIG. 8 but also a fourth upper surface 322 arranged in a direction farther away from the first area 1A than the third upper surface 321, the fourth upper surface 322 being in or overlapping the second bent area BA2. In an embodiment, as illustrated in the side view, a flat form of the fourth upper surface 322 may be defined by a seventh portion P7 and an eighth portion P8. The fourth upper surface 322 includes the seventh portion P7 and the eighth portion P8 among which the seventh portion P7 is closer to the first area A1, and the fourth upper surface 322 is oblique with respect to the display surface 200a such that a shortest distance to the display surface 200a from the seventh portion P7 is longer than a shortest distance to the display surface 200a from the eighth portion P8.

Particularly, a fourth virtual plane connecting the seventh portion P7 and the eighth portion P8, that is, the fourth upper surface 322, is more oblique with respect to the display surface 200a in the first area 1A than a third virtual plane connecting the fifth portion P5 and the sixth portion P6, that is, the third upper surface 321. Accordingly, an angle at which the light L_{BA2′} is incident to a surface of the second light adjustment layer 320 may be made greater than the case illustrated in FIG. 8. Consequently, an angle by which the light L_{BA2′} is refracted when passing through a surface of the second light adjustment layer 320, that is, the fourth upper surface 322, may be made larger. Therefore, as illustrated in FIG. 9, the quality of an image viewed by a user may be improved even further by allowing the light L_{BA2′} to travel in parallel with or approximately in parallel with the light L_{BA2}.

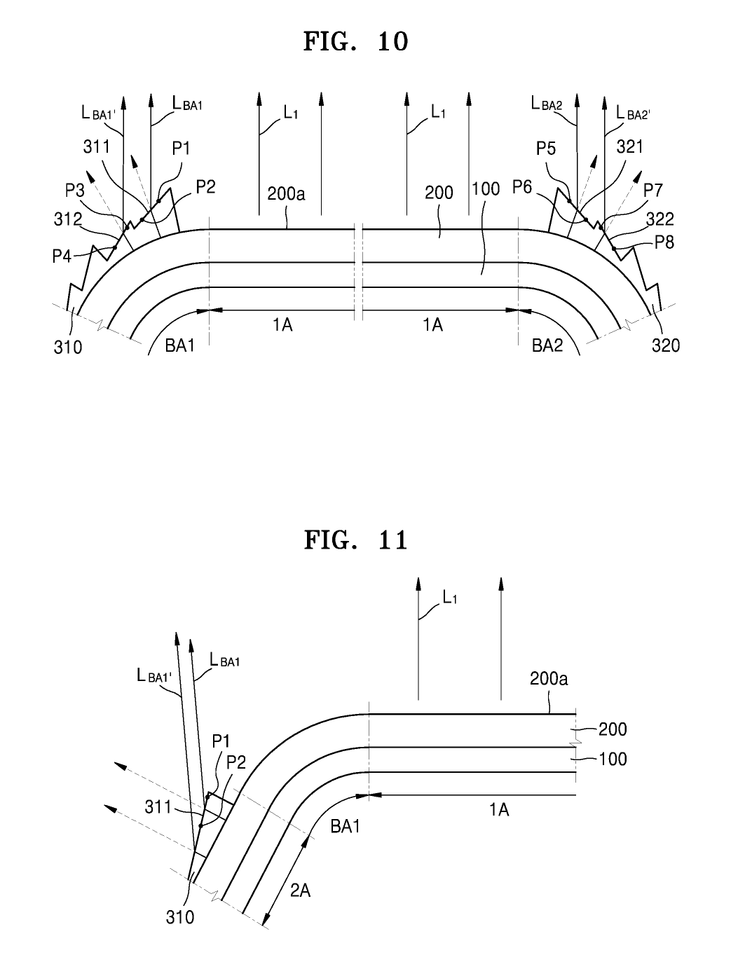

Although the third upper surface 321 and the fourth upper surface 322 of the second light adjustment layer 320 may be spaced apart from each other as illustrated in FIG. 9, embodiments are not limited thereto. For example, although the second light adjustment layer 320 may include a plurality of portions spaced apart from each other as illustrated in FIG. 9, the second light adjustment layer 320 may be formed as one body as illustrated in FIG. 10 showing a side view of a portion of a display device according to another embodiment. As shown in FIG. 10, in an embodiment, the third upper surface 321 may be connected to the fourth upper surface 322.

Although embodiments in which the first light adjustment layer 310 is arranged in the first bent area BA1 have been described, embodiments are not limited thereto. For example, as illustrated in FIG. 11, which is a side view of a portion of a display device according to another embodiment, the display unit 200 may be arranged in not only the first area 1A and the first bent area BA1 but also in the second area 2A. The display surface 200a may be arranged in at least a portion of the second area 2A. Also, the first light adjustment layer 310 may be arranged over the display surface 200a in or overlapping the second area 2A.

Even in this case, the first light adjustment layer 310 adjusts the travelling direction of light emitted from the display surface 200a in the second area 2A. For this, the first light adjustment layer 310 includes the first upper surface 311. As illustrated in the side view, the first upper surface 311 includes the first portion P1 and the second portion P2 among which the first portion P1 is closer to the first area 1A, and a shortest distance to the display surface 200a from the first portion P1 is longer than a shortest distance to the display surface 200a from the second portion P2. In an embodiment, the first upper surface 311 having a flat form is oblique with respect to the display surface 200a over the second area 2A.

Although the light L_{BA1} and the light L_{BA1′} emitted from the display surface 200a in the second area 2A travel in a direction perpendicular to the display surface 200a, the travelling directions of the light L_{BA1} and the light L_{BA1′} from the display surface 200a in the second area 2A are not parallel to the travelling direction of the light L₁ from the display surface 200a in the first area 1A due to existence of the first bent area BA1.

However, since the first light adjustment layer 310 is provided, the light L_{BA1} and the light L_{BA1′} change their travelling directions while passing through the first light adjustment layer 310. With the same/similar principle described in the above embodiments, the light L_{BA1} and the light L_{BA1′} are refracted toward the first area 1A while the light L_{BA1} and the light L_{BA1′} pass through the first upper surface 311 of the first light adjustment layer 310. Accordingly, the travelling direction of the light L_{BA1} may be parallel or approximately parallel to the travelling direction of the light L₁ in the first area 1A, as illustrated in FIG. 11. Therefore, the quality of a viewed image may be remarkably improved by allowing the image in the second area 2A to be viewed by a user with the color of the image undistorted or with a degree of distortion of the image remarkably reduced.

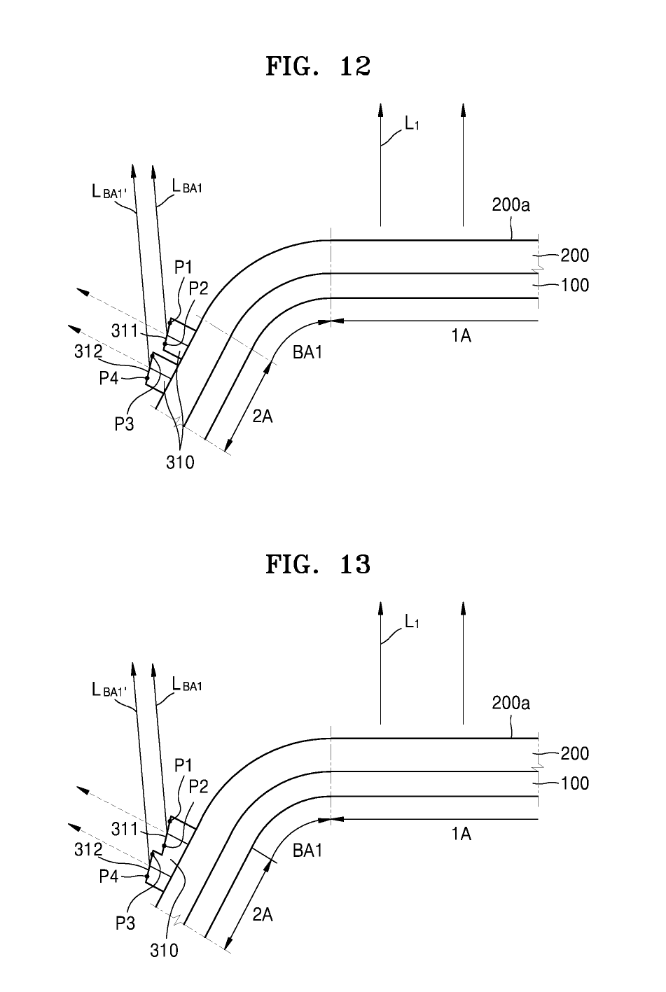

FIG. 12 is a side view of a portion of a display device according to another embodiment. In the display device according to the present embodiment, the first light adjustment layer 310 includes not only the first upper surface 311 described above but also the second upper surface 312 arranged in a direction farther away from the first area 1A than the first upper surface 311 over the second area 2A. As illustrated in the side view, a flat form of the second upper surface 312 may be defined by the third portion P3 and the fourth portion P4.

The second upper surface 312 includes the third portion P3 and the fourth portion P4 among which the third portion P3 is located closer to the first area 1A, and the second upper surface 312 is oblique with respect to the display surface 200a such that a shortest distance to the display surface 200a from the third portion P3 is longer than a shortest distance to the display surface 200a from the fourth portion P4. Particularly, the light L_{BA1} and the light L_{BA1′} passing through the first light adjustment layer 310 may be allowed to travel approximately in parallel with each other by allowing the first virtual plane connecting the first portion P1 and the second portion P2, that is, the first upper surface 311, to be parallel to the second virtual plane connecting the third portion P3 and the fourth portion P4, that is, the second upper surface 312.

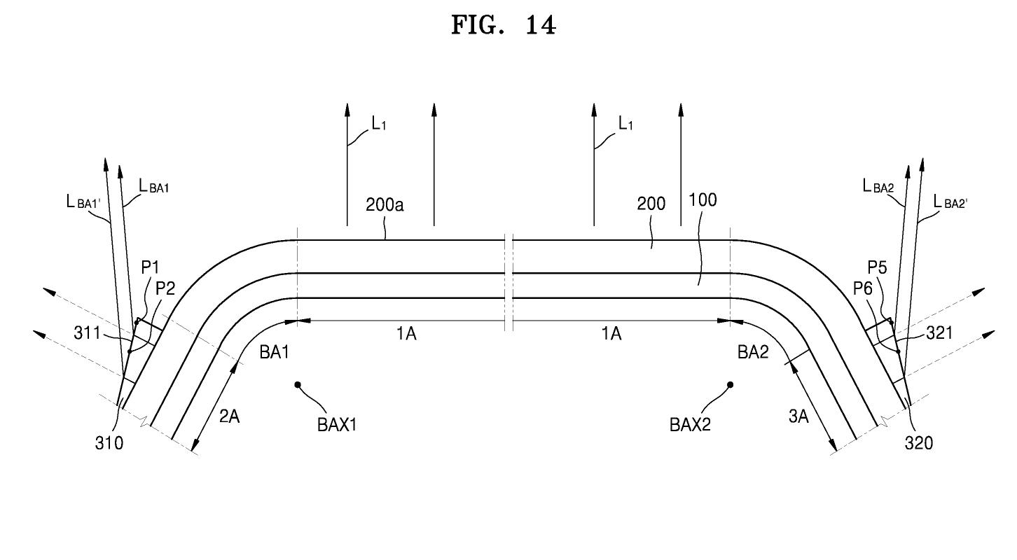

Although the first upper surface 311 and the second upper surface 312 of the first light adjustment layer 310 may be spaced apart from each other, embodiments are not limited thereto. Although the first light adjustment layer 310 may include a plurality of portions spaced apart from each other as illustrated in FIG. 12, in an embodiment, the first light adjustment layer 310 may be formed as one body as illustrated in FIG. 13 showing a side view of a portion of a display device according to another embodiment. In an embodiment, as shown in FIG. 13, the first upper surface 311 may be connected to the second upper surface 312.

Although embodiments have been described in which the substrate 100 of the display device includes the first area 1A, the first bent area BA1, and the second area 2A, as illustrated in FIG. 1, embodiments are not limited thereto. For example, as illustrated in FIG. 14, which is a side view of a portion of a display device according to another embodiment, the substrate 100 may include the third area 3A at a side of the first area 1A in a direction away from the second area 2A, and the second bent area BA2 arranged between the first area 1A and the third area 3A, the substrate being bent around a second bending axis BAX2 in the second bent area BA2. In this case, the display unit 200 may extend to not only the second bent area BA2 but also to the third area 3A, and the display surface 200a may even be provided over the third area 3A. In an embodiment, for reference, the second bending axis BAX2 may be parallel to the first bending axis BAX1.

Also, the second light adjustment layer 320 may be provided in the third area 3A. That is, the second light adjustment layer 320 is arranged over the display surface 200a in or overlapping the third area 3A. The second light adjustment layer 320 adjusts the travelling direction of light emitted from the display surface 200a in the third area 3A. For this, the second light adjustment layer 320 includes the third upper surface 321. As illustrated in the side view, the third upper surface 321 includes the fifth portion P5 and the sixth portion P6 among which the fifth portion P5 is located closer to the first area A1, and a shortest distance to the display surface 200a from the fifth portion P5 is longer than a shortest distance to the display surface 200a from the sixth portion P6. In an embodiment, the third upper surface 321 having a flat form is oblique with respect to the display surface 200a over the third area 3A.

Based on the same principle described for the first light adjustment layer 310, the second light adjustment layer 320 may improve the quality of a viewed image by allowing the image in the third area 3A to be viewed by a user with the color of the image undistorted or with a degree of distortion of the image remarkably reduced.

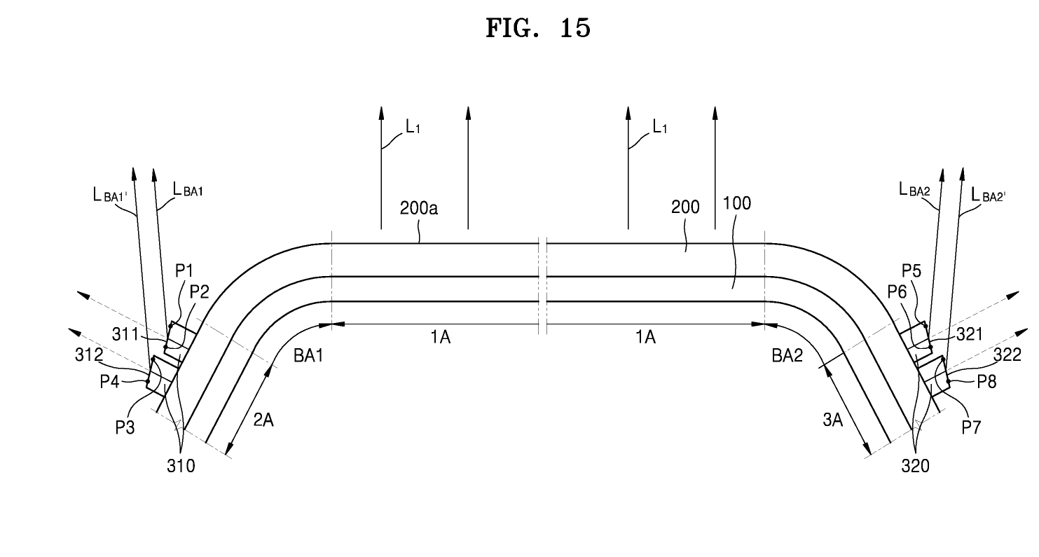

FIG. 15 is a side view of a portion of a display device according to another embodiment. In the display device according to the present embodiment, the first light adjustment layer 310 has the form described with reference to FIG. 12. Also, in an embodiment, the second light adjustment layer 320 is formed symmetrically with respect to the first light adjustment layer 310 about a virtual straight line passing through the center of the first area 1A and parallel to the first and second bending axes. That is, the second light adjustment layer 320 includes not only the third upper surface 321 described with reference to FIG. 14 but also the fourth upper surface 322 arranged in a direction farther away from the first area 1A than the third upper surface 321 over the third area 3A. As illustrated in the side view, a flat form of the fourth upper surface 322 may be defined by the seventh portion P7 and the eighth portion P8.

The fourth upper surface 322 includes the seventh portion P7 and the eighth portion P8 among which the seventh portion P7 is located closer to the first area A1, and the fourth upper surface 322 is oblique with respect to the display surface 200a such that a shortest distance to the display surface 200a from the seventh portion P7 is longer than a shortest distance to the display surface 200a from the eighth portion P8. Particularly, the light L_{BA2} and the light L_{BA2′} passing through the second light adjustment layer 320 may be allowed to travel approximately in parallel with each other by allowing the third virtual plane connecting the fifth portion P5 and the sixth portion P6, that is, the third upper surface 321, to be parallel to the fourth virtual plane connecting the seventh portion P7 and the eighth portion P8, that is, the fourth upper surface 322.

Although the third upper surface 321 and the fourth upper surface 322 of the second light adjustment layer 320 may be spaced apart from each other, embodiments are not limited thereto. Although the second light adjustment layer 320 may include a plurality of portions spaced apart from each other as illustrated in FIG. 15, in an embodiment, the second light adjustment layer 320 may be formed as one body in a similar manner as the first light adjustment layer 310 illustrated in FIG. 13. In an embodiment, the third upper surface 321 may be connected to the fourth upper surface 322 to form a saw-toothed shape when viewed from a side view. In an embodiment, the third upper surface 321 and the fourth upper surface 322 may be chamfered or rounded such that pointed end portions thereof are chamfered or rounded.

Although the present disclosure has been described with reference to the example embodiments illustrated in the drawings, these are merely provided as some examples, and it will be understood by those of ordinary skill in the art that various changes in form and details and equivalents thereof may be made therein without departing from the spirit and scope of the disclosure as set forth in the following claims.

What is claimed is:

1. A display device comprising:
a substrate comprising a first area, a second area, and a first bent area between the first area and the second area, the substrate being bent around a first bending axis in the first bent area;
a display surface over the substrate in the first area and the first bent area; and
a first light adjustment layer over the display surface and overlapping the first bent area, the first light adjustment layer comprising a first upper surface, the first upper surface including a first portion and a second portion, the first portion being located closer to the first area than the second portion, the first upper surface being oblique with respect to the display surface such that a shortest distance to the display surface from the first portion is longer than a shortest distance to the display surface from the second portion.

2. The display device of claim 1, wherein the first light adjustment layer further comprises a second upper surface over the display surface and overlapping the first bent area such that the second upper surface is arranged farther away from the first area than the first upper surface, the second upper surface including a third portion and a fourth portion, the third portion being located closer to the first area than the fourth portion, the second upper surface being oblique with respect to the display surface such that a shortest distance to the display surface from the third portion is longer than a shortest distance to the display surface from the fourth portion.

3. The display device of claim 2, wherein a second virtual plane connecting the third portion and the fourth portion is more oblique with respect to the display surface in the first area than a first virtual plane connecting the first portion and the second portion.

4. The display device of claim 1, wherein the first upper surface and the second upper surface are spaced apart from each other.

5. The display device of claim 1, wherein the first upper surface and the second upper surface are connected to each other.

6. The display device of claim 1, wherein the substrate comprises a third area at a side of the first area in a direction away from the second area, and a second bent area between the first area and the third area, the substrate being bent around a second bending axis in the second bent area,
the display surface extends to the second bent area, and
the display device further comprises a second light adjustment layer over the display surface and overlapping the second bent area, the second light adjustment layer comprising a third upper surface, the third upper surface including a fifth portion and a sixth portion, the fifth portion being located closer to the first area than the sixth portion, the third upper surface being oblique with respect to the display surface such that a shortest distance to the display surface from the fifth portion is longer than a shortest distance to the display surface from the sixth portion.

7. The display device of claim 6, wherein the second bending axis is parallel to the first bending axis.

8. The display device of claim 6, wherein the second light adjustment layer further comprises a fourth upper surface over the display surface and overlapping the second bent area such that the fourth upper surface is arranged farther away from the first area than the third upper surface, the fourth upper surface including a seventh portion and an eighth portion, the seventh portion being located closer to the first area than the eighth portion, the fourth upper surface being oblique with respect to the display surface such that a shortest distance to the display surface from the seventh portion is longer than a shortest distance to the display surface from the eighth portion.

9. The display device of claim 8, wherein a fourth virtual plane connecting the seventh portion and the eighth portion is more oblique with respect to the display surface in the first area than a third virtual plane connecting the fifth portion and the sixth portion.

10. The display device of claim 8, wherein the third upper surface and the fourth upper surface are spaced apart from each other.

11. The display device of claim 8, wherein the third upper surface and the fourth upper surface are connected to each other.

12. A display device comprising:
a substrate comprising a first area, a second area, and a first bent area between the first area and the second area, the substrate being bent around a first bending axis in the first bent area;
a display surface over the substrate in the first area, the first bent area, and the second area; and
a first light adjustment layer over the display surface and overlapping the second area, the first light adjustment layer comprising a first upper surface, the first upper surface including a first portion and a second portion, the first portion being located closer to the first area than the second portion, the upper surface being oblique with respect to the display surface such that a shortest distance to the display surface from the first portion is longer than a shortest distance to the display surface from the second portion.

13. The display device of claim 12, wherein the first light adjustment layer further comprises a second upper surface over the display surface and overlapping the second area such that the second upper surface is arranged farther away from the first area than the first upper surface, the second upper surface including a third portion and a fourth portion, the third portion being located closer to the first area than the fourth portion, the second upper surface being oblique with respect to the display surface such that a shortest distance to the display surface from the third portion is longer than a shortest distance to the display surface from the fourth portion.

14. The display device of claim 13, wherein a first virtual plane connecting the first portion and the second portion is parallel to a second virtual plane connecting the third portion and the fourth portion.

15. The display device of claim 13, wherein the first upper surface and the second upper surface are spaced apart from each other.

16. The display device of claim 13, wherein the first upper surface and the second upper surface are connected to each other.
